(19) United States
(12) Patent Application Publication
(10) Pub. No.: US 2024/0349552 A1
(43) Pub. Date: Oct. 17, 2024

(54) DISPLAY PANEL AND DISPLAY DEVICE

(71) Applicant: Wuhan Tianma Micro-Electronics Co., Ltd., Wuhan (CN)

(72) Inventors: Chao PENG, Wuhan (CN); Zhongjie ZHANG, Wuhan (CN)

(21) Appl. No.: 18/235,639

(22) Filed: Aug. 18, 2023

(30) Foreign Application Priority Data
Apr. 12, 2023 (CN) 202310396404.6

(51) Int. Cl. H10K 59/131

(52) U.S. Cl. CPC H10K 59/131; H10K 2102/311

(57) ABSTRACT

A display panel includes a display area, a non-display area, a wire routing area, a base substrate, a first insulating layer, a first metal layer, and a second insulating layer. The wire routing area is located in the non-display area. The first metal layer is located between the first insulating layer, including a first via hole exposing at least part of the first metal layer, and the base substrate. The second insulating layer, in contact with the first metal layer, is located between the first metal layer and the base substrate. Along a thickness direction of the display panel, a distance from a side surface of the second insulating layer away from the base substrate to a side surface of the base substrate close to the second insulating layer has D1 in the wire routing area and D2 in the display area, D1>D2>0.

### CROSS-REFERENCE TO RELATED APPLICATION

This application claims priority to Chinese Patent Application No. 202310396404.6, filed on Apr. 12, 2023, the entire content of which is incorporated herein by reference.

### TECHNICAL FIELD

The present disclosure relates to the field of display technology and, in particular, to a display panel and a display device.

### BACKGROUND

When a display device includes a touch function, if an embedded design is adopted, a light-emitting device layer is usually packaged first, and a touch signal wire is arranged on the side of the package layer away from the base substrate. The touch signal wire extends to a non-display area and is routed to the bottom of the package layer through a via hole. When making the display panel, a routing hole is arranged at the routing place of the touch signal wire. During packaging the display panel, the material of the package layer may easily enter the routing hole, thereby affecting the electrical connection quality between the subsequent touch signal wire and an underlying film layer at the routing hole.

### SUMMARY

One aspect of the present disclosure provides a display panel. The display panel includes a display area and a non-display area; a wire routing area, located in the non-display area; a base substrate, a first insulating layer and a first metal layer. The first metal layer is located between the first insulating layer and the base substrate. The first insulating layer includes a first via hole exposing at least part of the first metal layer. The second insulating layer is located between the first metal layer and the base substrate. The second insulating layer is in contact with the first metal layer. In the wire routing area, along a thickness direction of the display panel, a distance from a side surface of the second insulating layer away from the base substrate to a side surface of the base substrate close to the second insulating layer being D1. In the display area, along the thickness direction of the display panel, a distance from the side surface of the second insulating layer away from the base substrate to the side surface of the base substrate close to the second insulating layer being D2, and D1>D2>0.

Another aspect of the present disclosure provides a display device that includes a display panel. The display panel includes a display area and a non-display area; a wire routing area, located in the non-display area; a base substrate, a first insulating layer and a first metal layer. The first metal layer is located between the first insulating layer and the base substrate. The first insulating layer includes a first via hole exposing at least part of the first metal layer. The second insulating layer is located between the first metal layer and the base substrate. The second insulating layer is in contact with the first metal layer. In the wire routing area, along a thickness direction of the display panel, a distance from a side surface of the second insulating layer away from the base substrate to a side surface of the base substrate close to the second insulating layer being D1. In the display area, along the thickness direction of the display panel, a distance from the side surface of the second insulating layer away from the base substrate to the side surface of the base substrate close to the second insulating layer being D2, and D1>D2>0.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 is a schematic structural diagram of a display panel according to embodiments of the present disclosure.

FIG. 2 is a cross-sectional view taken along line D-D of the display panel in FIG. 1 according to embodiments of the present disclosure.

FIG. 3 is another cross-sectional view taken along line D-D of the display panel in FIG. 1 according to embodiments of the present disclosure.

FIG. 4 is a schematic circuit diagram of a pixel circuit of the display panel according to embodiments of the present disclosure.

FIG. 5 is another cross-sectional view taken along line D-D of the display panel in FIG. 1 according to embodiments of the present disclosure.

FIG. 6 is another cross-sectional view taken along line D-D of the display panel in FIG. 1 according to embodiments of the present disclosure.

FIG. 7 is another cross-sectional view taken along line D-D of the display panel in FIG. 1 according to embodiments of the present disclosure.

FIG. 8 is another cross-sectional view taken along line D-D of the display panel in FIG. 1 according to embodiments of the present disclosure.

FIG. 9 is a schematic diagram of the routing of the first binding wire in the display panel according to embodiments of the present disclosure.

FIG. 10 is a cross-sectional view taken along line E-E of the display panel in FIG. 1 according to embodiments of the present disclosure.

FIG. 11 is a cross-sectional view taken along line F-F of the display panel in FIG. 1 according to embodiments of the present disclosure.

FIG. 12 is another cross-sectional view taken along line F-F of the display panel in FIG. 1 according to embodiments of the present disclosure.

FIG. 13 is another cross-sectional view taken along line F-F of the display panel in FIG. 1 according to embodiments of the present disclosure.

FIG. 14 is another cross-sectional view taken along line E-E of the display panel in FIG. 1 according to embodiments of the present disclosure.

FIG. 15 is a schematic diagram of the routing of the second binding wire in the display panel according to embodiments of the present disclosure.

FIG. 16 is a top view of the touch layer of the display panel according to embodiments of the present disclosure.

FIG. 17 is another cross-sectional view taken along line E-E of the display panel in FIG. 1 according to embodiments of the present disclosure.

FIG. 18 is a schematic structural diagram of a display device according to embodiments of the present disclosure.

### DETAILED DESCRIPTION OF THE EMBODIMENTS

Features and exemplary embodiments of various aspects of the present disclosure will be described in detail below. In the following detailed description, specific details are set forth in order to provide a comprehensive understanding of the present disclosure. It will be apparent, however, to persons of ordinary skill in the art that the present application can be practiced without some of these specific details. The description of the embodiments below is intended to illustrate examples of the present application for a better understanding thereof.

It should be noted that, unless there are conflicts otherwise, the embodiments and features described in some embodiments of the present disclosure can be combined with each other. Embodiments of the present disclosure will be described in detail below in conjunction with the accompanying drawings.

The terms such as “first” and “second” are used merely to distinguish one entity or operation from another entity or operation, and do not necessarily require or imply any actual relationship or order between these entities or operations. Additionally, the terms “comprising”, “including”, or any other variant thereof, are intended to encompass a non-exclusive inclusion, such that a process, method, article, or apparatus comprising a series of elements includes not only those elements explicitly listed, but also include other elements that are not explicitly listed but are inherent to such process, method, article, or apparatus. In the absence of further limitations, an element defined by a statement that includes the term “comprising” does not exclude the presence of additional identical elements in a process, method, article, or apparatus that includes the element.

It should be understood that when describing the structure of a component, when referring to one layer or region as being “above” or “on top of” another layer or region, it could mean directly above or on top of another layer or region, or it could include other layers or regions between the layer and another layer or region. Furthermore, if the component is flipped, the layer or region will be located “below” or “underneath” another layer or region.

In addition, the term “and/or” in the present disclosure simply a way of describing the relationship between associated objects, indicating that there may be three relationships, for example, A and/or B may represent the following three situations: A exists alone, both A and B exist, and B exists alone. In addition, the character “/” in the present disclosure generally represents an “or” relationship between the associated objects before and after it.

It should be understood that in embodiments of the present disclosure, “B corresponding to A” means that B is related to A, and B can be determined according to A. However, it should also be understood that determining B according to A does not necessarily mean that B can only be determined according to A, B may also be determined based on A and/or other information.

It should be understood that various modifications and changes can be made in the present disclosure without departing from the spirit or scope of the present disclosure, which would be apparent to those persons of ordinary skill in the art. Accordingly, the present disclosure is intended to cover modifications and changes falling within the scope of the corresponding claims the technical solution to be protected and their equivalents. It should be noted that the embodiments provided in the present disclosure can be combined with each other as long as they are not contradictory.

In current display devices, a touch signal wire is usually routed at a non-display area of a display panel. For example, when a touch layer is arranged in a display device, the touch layer is generally arranged on the side of a light-emitting device layer away from a base substrate, while a chip for processing the touch signal is usually arranged in a lower border region located on the side of the light-emitting device layer facing the base substrate. The touch signal wire needs to be connected to the solder pad corresponding to chip pins by crossing a bending area of the lower border region. Therefore, the touch signal wire needs to be routed in the non-display area of the display panel to enhance their bending resistance in the bending area. A via hole is usually arranged at a wire routing place of the touch signal wire so that the touch signal wire on one side of the light-emitting device layer can be electrically connected to the corresponding connecting signal wire on the other side of the light-emitting device layer, and then through the connecting signal wire to be electrically connected to the chip to achieve the transmission of the touch signal. In the process of manufacturing the display panel, the display panel needs to be packaged, i.e., a packaging layer is prepared. Generally, chemical vapor deposition CVD is used to prepare the packaging layer. During the preparation process, since a CVD mask plate will block the via hole for wire routing, there is a gap between the mask plate and the underlying film layer. Materials of the packaging layer may enter the position of the via hole through the gap, which will affect the electrical connection between the touch signal wire and the corresponding connecting signal wire at the via hole and thus affect the transmission of the touch signal.

Based on the above analysis, the applicant proposes a display panel, including a first insulating layer, a first metal layer, a second insulating layer, and a base substrate stacked in sequence. The first insulating layer has a first via hole located in the wire routing area. The first via hole exposes the first metal layer for the routing of the first connecting signal wire. A distance from a side surface of the second insulating layer away from the base substrate to a side surface of the base substrate close to the second insulating layer is D1 corresponding to a distance of the second insulating layer in the wire routing area. The distance from a side surface of the second insulating layer away from the base substrate to a side surface of the base substrate close to the second insulating layer is D2 corresponding to a distance of the second insulating layer in the display area. D1 is greater than D2, causing the first insulating layer located in the wire routing area to be higher than the first insulating layer located in the display area. When preparing the packaging layer, the first via hole located in the wire routing area will be closer to the CVD mask plate, making it more difficult for the packaging layer material to enter the first via hole, thereby improving the electrical connection quality between the first signal wire and the first metal layer at the first via hole.

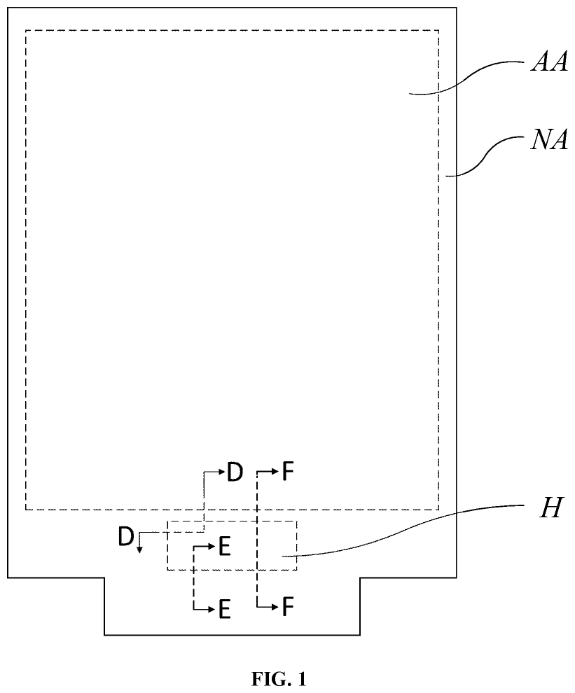

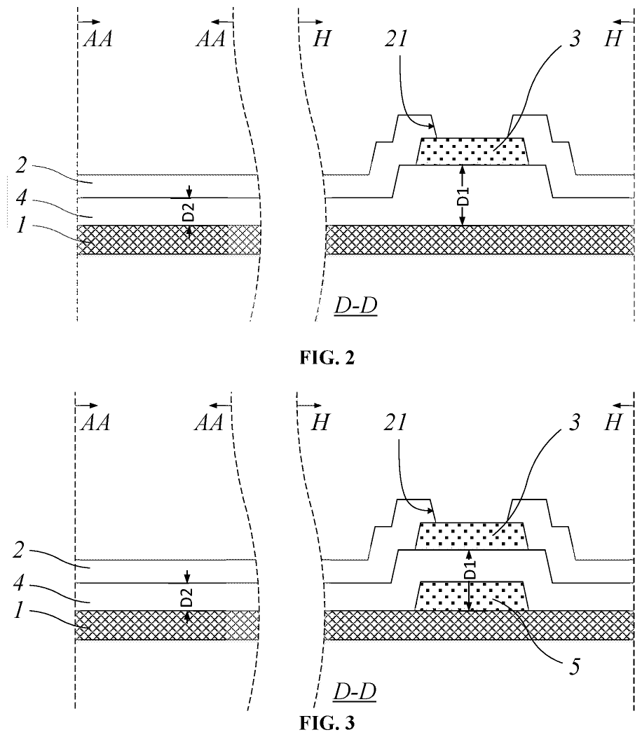

FIG. 1 is a schematic structural diagram of a display panel according to embodiments of the present disclosure. FIG. 2 is a cross-sectional view taken along line D-D of the display panel in FIG. 1 according to embodiments of the present disclosure.

Please refer to FIG. 1 and FIG. 2. Some embodiments of the present disclosure provide a display panel, including a display area AA and a non-display area NA; A wire routing area H located in the non-display area NA, a base substrate 1, a first insulating layer 2, and a first metal layer 3 located between the first insulating layer 2 and the base substrate 1; The first insulating layer 2 includes a first via hole 21 located in the wire routing area H. The first via hole 21 exposes at least a portion of the first metal layer 3. The display panel also includes a second insulating layer 4 located between the first metal layer 3 and the base substrate 1. The second insulating layer 4 contacts the first metal layer 3. In the wire routing area H, along a thickness direction of the display panel, a distance from a side surface of the second insulating layer 4 away from the base substrate 1 to a side surface of the base substrate 1 close to the second insulating layer 4 is D1; In the display area AA, along the thickness direction of the display panel, the distance from the side surface of the second insulating layer 4 away from the base substrate 1 to the side surface of the base substrate 1 close to the second insulating layer 4 is D2; D1>D2>0.

In some embodiments of the present disclosure, the display area AA of the display panel is used for displaying light emission. The non-display area NA at least partially surrounds the display area AA. The wire routing area H is located in the non-display area NA and used for routing the first connecting signal wire, where the first connecting signal wire is electrically connected to a second connecting signal wire in the wire routing area H. Exemplarily, the first connecting signal wire may be a touch signal wire of a touch layer and the second connecting signal wire may be electrically connected to a solder pad corresponding to a chip pin to transmit the touch signal via the first and second signal wires.

The base substrate 1 covers the display area AA and the non-display area NA, and be used as a carrier for other film layers of the display panel. The base substrate 1 can be made of polymer materials including, glass, polyimide (PI), polycarbonate (PC), polyethersulfone (PES), polyethylene terephthalate (PET), polyethylene naphthalate (PEN), polyarylates (PAR) or glass fiber reinforced plastics (FRP). The base substrate 1 may be transparent, semi-transparent, or opaque. The base substrate 1 in some embodiments of the present disclosure may also be a flexible base substrate formed by a thin polymer material such as polyimide.

The first insulating layer 2 is located on one side of the first metal layer 3 away from the base substrate 1. The first insulating layer 2 is used for insulating the first metal layer 3 from the metal film layer on the other side of the first insulating layer 2, except at the via hole. The first via hole 21 located in the wire routing area H exposes the first metal layer 3, allowing the first connecting signal wire can be electrically connected to the first metal layer 3 at the first via hole to achieve the routing of the first connecting signal wire. As the second insulating layer 4 is located between the first metal layer 3 and the base substrate 1, the second insulating layer 4 can be used for insulating the first metal layer 3 from the metal film layer on other side of the second insulating layer 4. The first insulating layer 2, the first metal layer 3, and the second insulating layer 4 are partially located in the display area AA and partially located in the wiring area H.

Along the thickness direction of the display panel, within the range of the display area AA and the non-display area NA, the distance from the side of the second insulating layer 4 away from the base substrate 1 to the side of the base substrate 1 close to the second insulating layer 4 varies. D1 corresponds to the distance in the display area AA and D2 corresponds to the distance in the wire routing area H, satisfying D1>D2>0. Therefore, the second insulating layer 4 in the wire routing area H is farther away from the substrate 1 than the second insulating layer 4 in the display area AA. As the first metal layer 3 is in contact with the second insulating layer 4, the first insulating layer 2 is located on the side of the first metal layer 3 away from the second insulating layer 4. Therefore, the first insulating layer 2 in the area AA is farther away from the base substrate 1 than the first insulating layer 1 in the display area AA. When the packaging layer is prepared on the side of the first insulating layer 2 away from the base substrate 1, the first insulating layer 2 located in the wire routing area H will be closer to the mask plate than the first insulating layer 2 located in the display area AA. That is to say, the first via hole 21 located in the first insulating layer 2 will be closer to the mask plate. Therefore, it is more difficult for the material of the packaging layer to enter the first via hole 21 from the gap between the mask plate and the first insulating layer 2, which improves the quality of the electrical connection between the first connecting signal wire and the first metal layer 3, making the signal transmission of the first connecting signal wire smoother.

It should be noted that the first connecting signal wire that is routed in the wire routing area H should meet the requirement of wire routing between different layers of the display panel. Exemplarily, the first connecting signal wire that is routed can be the touch signal wire of the touch layer, or a feedback signal wire of the light sensor. The second connecting signal wire in another layer of the display panel corresponding to the first connecting signal wire can be arranged on the first metal layer 3, or between the first metal layer 3 and the base substrate 1. If it is arranged between the first metal layer 3 and the base substrate 1, the second connecting signal wire needs to be electrically connected to the first metal layer 3. Each of second connecting signal wires is electrically connected to a first connecting signal wire respectively to achieve signal transmission. Exemplarily, the second connecting signal wire can be electrically connected to the touch chip to transmit the touch signal.

In addition, the second insulating layer 4 can directly contact the base substrate 1, and additional film layers can also be arranged between the second insulating layer 4 and the base substrate 1. For example, a planarization layer as well as additional metal layers and insulating layers can be arranged between the second insulating layer 4 and the base substrate 1.

FIG. 3 is another cross-sectional view taken along line D-D of the display panel in FIG. 1 according to embodiments of the present disclosure.

Referring to FIG. 3, the display panel of some embodiments of the present disclosure further includes a first metal spacer 5 located in the wire routing area H. The first metal spacer 5 is arranged between the second insulating layer 4 and the base substrate 1.

The spacer of the first metal layer 3 located in the wire routing area H is arranged between the second insulating layer 4 and the base substrate 1. Compared with the display area AA, the first metal spacer 5 can keep the second insulating layer 4 located in the wire routing area H away from the base substrate 1, increasing the distance D1 that is from the side of the second insulating layer 4 away from the base substrate 1 to the of base substrate 1 close to the second insulating layer 4 and ensuring D1>D2. During the preparation of the packaging layer, the first via hole 21 in the first insulating layer 2 can be arranged closer to the mask plate to reduce the possibility of packaging material entering the first via hole 21 and to improve the quality of the electrical connection between the first connecting signal wire and the first metal layer 3, making the signal transmission of the first connecting signal wire smoother.

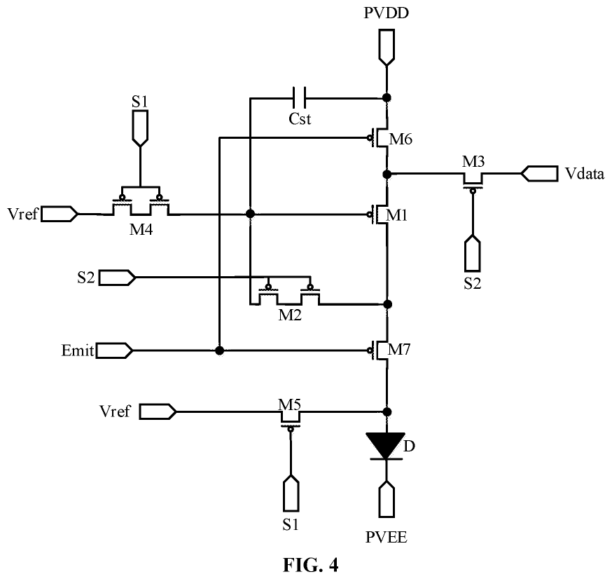

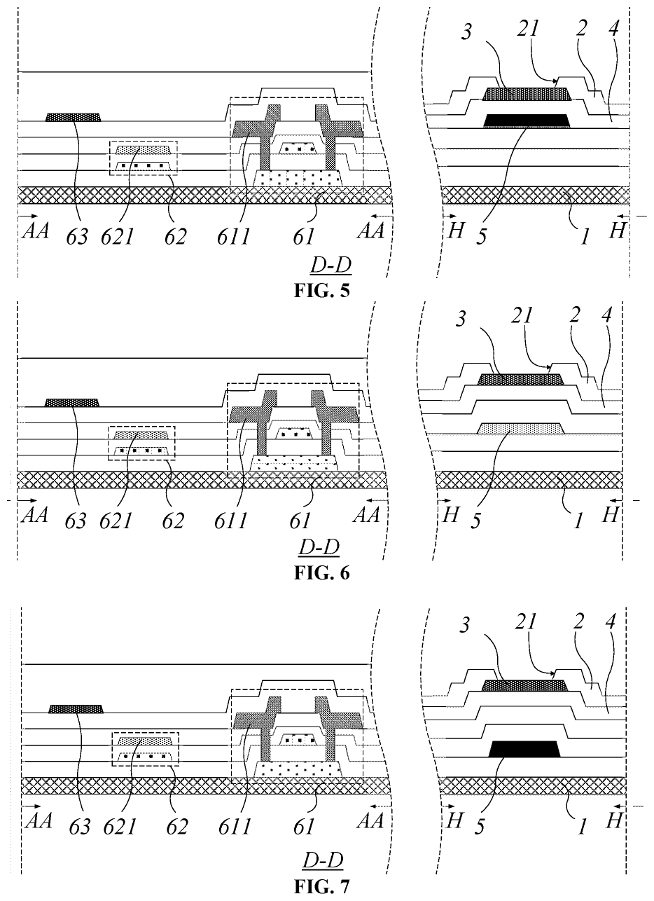

FIG. 4 is a schematic circuit diagram of a pixel circuit of the display panel according to embodiments of the present disclosure. FIG. 5 is another cross-sectional view taken along line D-D of the display panel in FIG. 1 according to embodiments of the present disclosure. FIG. 6 is another cross-sectional view taken along line D-D of the display panel in FIG. 1 according to embodiments of the present disclosure. FIG. 7 is another cross-sectional view taken along line D-D of the display panel in FIG. 1 according to embodiments of the present disclosure.

Further, please refer to FIG. 4 to FIG. 7, the display area AA includes a plurality of thin film transistors 61, a plurality of capacitors 62, and a plurality of first signal wires 63. A thin film transistor of the plurality of thin film transistors 61 includes a first transistor electrode 611. A capacitor of the plurality of capacitors 62 includes the first capacitor electrode 621. The first transistor electrode 611, the first capacitor electrode 621, and a first signal wire of the plurality of first signal wires 63 are arranged in different layers. The first signal wire 63 is located in the first metal layer 3. The first metal spacer 5 and at least one of the first transistor electrode 611 and the first capacitor electrode 621 are arranged in the same layer.

The thin film transistor 61, capacitor 62, and first signal wire 63 in the display area AA can be used to form a pixel circuit of the display panel to control the light-emitting device 64 of the display panel. For the convenience of description, some embodiments of the present disclosure use an example of a pixel circuit including seven thin film transistors 61 and one capacitor 62 (7T1C pixel circuit). The pixel circuit of some embodiments of the present disclosure may also adopt other forms of pixel circuits, such as 7T2C, 8T1C, 8T2C, 9T1C, and 9T2C.

A thin film transistor M1 may be a driving transistor. A thin film transistor M2 may be a threshold compensation transistor. A thin film transistor M3 may be a data writing transistor. A thin film transistor M4 may be a first reset transistor. A thin film transistor M5 may be a second reset transistor. A transistor M6 may be a first light-emission control transistor. A thin film transistor M7 may be a second light-emission control transistor. A capacitor Cst may be a storage capacitor. A signal wire S1 may be a first scanning signal wire. A signal wire S2 may be a second scanning signal wire. A signal wire Verf can be a reference voltage signal wire. A signal wire Emit can be a light-emitting control signal wire. A signal wire Vdata can be a data signal wire. A signal wire PVDD can be a first power signal wire. A signal wire PVEE can be a second power signal wire. Among them, the thin film transistor M4 and the thin film transistor M5 can be connected to different reference (reset) voltage signal wires; Each thin film transistor can be set as a P-type or an N-type transistor according to design requirements. In FIG. 4, all transistors are shown as P-type transistors for illustrative purposes.

In some embodiments of the present disclosure, the first signal wire 63 may be the first power signal wire PVDD, the capacitor 62 may be the storage capacitor Cst, and the thin film transistor 61 may be the first light emission control transistor M6 or the second light-emission control transistor M7.

Exemplarily, the first transistor electrode 611 of the thin film transistor 61 may be a gate electrode or a drain electrode. The first capacitor electrode 621 of the capacitor 62 can be any one electrode of the capacitors 62. The first signal wire 63 may be a positive power wire. The first transistor electrode 611, the first capacitor electrode 621, and the first signal wire 63 are arranged in different layers. Generally, along the thickness direction of the display panel, the first transistor electrode 611 and the first capacitor electrode 621 can be located between the first signal wire 63 and base substrate 1. Therefore, the first signal wire 63 is located in the first metal layer 3, and the first metal spacer 5 and at least one of the first transistor electrode 611 and the first capacitor electrode 621 are arranged on the same layer. The part of the first metal layer 3 exposed in the first via hole 21 and the first signal wire 63 can be fabricated simultaneously, which facilitates the fabrication of the part of the first metal layer 3 exposed in the first via hole 21 without significantly increasing the thickness of the display surface in some embodiments of the present disclosure. It is also possible to make the first metal spacer 5 and the first transistor electrode 611 simultaneously, and/or, to make the first metal spacer 5 and the first capacitor electrode 621 simultaneously, facilitating manufacturing the first metal spacer 5 and ensuring that the distance from the first via hole 21 of the first insulating layer 2 to the base substrate 1 is greater than the distance from the first insulating layer 2 to the base substrate 1 in the display area AA. The number of the first metal spacer 5 should be at least one, and each first metal spacer 5 is respectively arranged on the same layer as one of the first transistor electrode 611 and the first capacitor electrode 621.

Further, referring to FIG. 5 to FIG. 7, in the thickness direction of the display panel, the first metal spacer 5 at least partially overlaps with the first via hole 21.

In some embodiments of the present disclosure, the first metal spacer 5 is used to make the distance from the first via hole 21 of the first insulating layer 2 to the base substrate 1 larger than the distance from the first insulating layer 2 to the base substrate 1 in the display area AA. Since the first metal spacer 5 and the first via hole 21 at least partially overlap, at least an area of the first insulating layer 2, located in the wire routing area H, overlapping with the first metal spacer 5 can satisfy the condition that its distance to the base substrate 1 is greater than its distance between the first substrate layer 2 and the base substrate 1 in the display area AA, reducing the risk of packaging material entering the first via hole 21 and improving the electrical connection quality at the first via hole 21. Exemplarily, when the first via hole 21 is a circular hole, the first spacer can also be a circular spacer; on the plane where the base substrate 1 is located, the orthographic projection of the first via hole 21 is located in the orthographic projection of the first spacer.

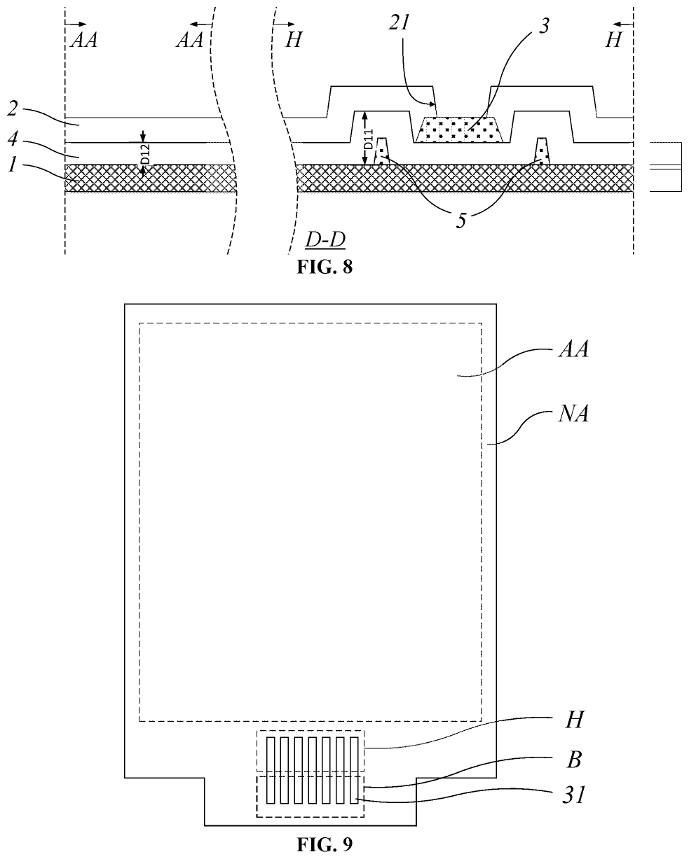

FIG. 8 is another cross-sectional view taken along line D-D of the display panel in FIG. 1 according to embodiments of the present disclosure.

Further, please refer to FIG. 8, in the thickness direction of the display panel, at least part of the first metal spacer 5 does not overlap with the first via hole 21.

Since at least part of the first metal spacer 5 does not overlap with the first via hole 21, the first metal spacer 5 will cause a distance from the first insulating layer 2 located in the wire routing area H and outside the first via hole 21 to the base substrate 1 to be greater than the distance between the first insulating layer 2 and the base substrate 1 in the display area AA. Meanwhile, the distance between the first insulating layer 2 at the first via hole 21 and the base substrate 1 can be greater than or equal to the distance between the first insulating layer 2 and the base substrate 1 in the display area AA. Exemplarily, when the first via hole 21 is a circular hole, the first spacer can be an annular spacer; on the plane where the base substrate 1 is located, the orthographic projection of the first spacer surrounds the orthographic projection of the first via hole 21.

Further, referring to FIG. 8, in the wire routing area H, along the thickness direction of the display panel, the distance from the side surface of the second insulating layer 4, covering the first metal spacer 5 and away from the base substrate 1, to the side surface of the base substrate 1, close to the second insulating layer 4 is D11; In the wire routing area H, along the thickness direction of the display panel, a distance from the side surface of the part of second insulating layer 4 not covering the first metal spacer 5 and away from the base substrate 1 to the side surface of the base substrate 1 close to the second insulating layer 4 is D12, where D11>D12>0.

Along the thickness direction of the display panel, in the non-display area, a distance from a side of the second insulating layer 4 away from the base substrate 1 to a side of the base substrate 1 close to the second insulating layer 4 varies. The distance D11 corresponding to a portion covering the first metal spacer 5 and the distance D12 corresponding to a portion not covering the first metal spacer 5, satisfying D11>D12>0. Therefore, the second insulating layer 4 covering the first metal spacer 5 is farther away from the base substrate 1 than the second insulating layer 4 not covering the first metal spacer 5. Since the first metal layer 3 is in contact with the second insulating layer 4, the first insulating layer 2 is located on the side of the first metal layer 3 away from the second insulating layer 4. Therefore, the first insulating layer 2 covering the first metal spacer 5 will be farther away from the base substrate 1 than the first insulating layer 2 that not covering the first metal spacer 5. Considering that on the plane where the base substrate 1 is located, the orthographic projection of the first spacer surrounds the orthographic projection of the first via hole 21, the portion of the first insulating layer 2 covering the first metal spacer 5 can also prevent the packaging layer material from entering the first via hole 21, improving the electrical connection quality between the first via hole 21 and the signal wire before the wire routing.

FIG. 9 is a schematic diagram of the routing of the first binding wire in the display panel according to embodiments of the present disclosure.

Further, please refer to FIG. 9, the non-display area NA also includes a bending area B, and the wire routing area H is located between the bending area B and the display area AA; The first metal layer 3 includes a first binding wire 31 and at least part of the first binding wire 31 located in the bending area B; The first via hole 21 exposes at least part of the first binding wire 31.

The display panel in some embodiments of the present disclosure can be electrically connected to a circuit board with a chip through binding. In order to increase the proportion of the display area AA, the binding area and the circuit board with the chip can be bent to a side of the base substrate 1 away from the first metal layer 3. In some embodiments of the present disclosure, the bending area B of the non-display area NA can be bent. In some embodiments of the present disclosure, after the display panel is bound to the circuit board with the chip, the bending area B can be bent so that the circuit board with the chip is bent to the side of the base substrate 1 away from the first metal layer 3, increasing the proportion of the display area AA. At least a part of the first binding wire 31 of the first metal layer 3 is located in the bending area B and is used as a second connecting signal wire. When the first connecting signal wire is routed, the first connecting signal wire can be electrically connected to the first binding wire 31 in the first via hole 21 to achieve the purpose of routing. Optionally, after the display panel of embodiments of present disclosure is bound, the first binding wire 31 can be bent together with the bending area B.

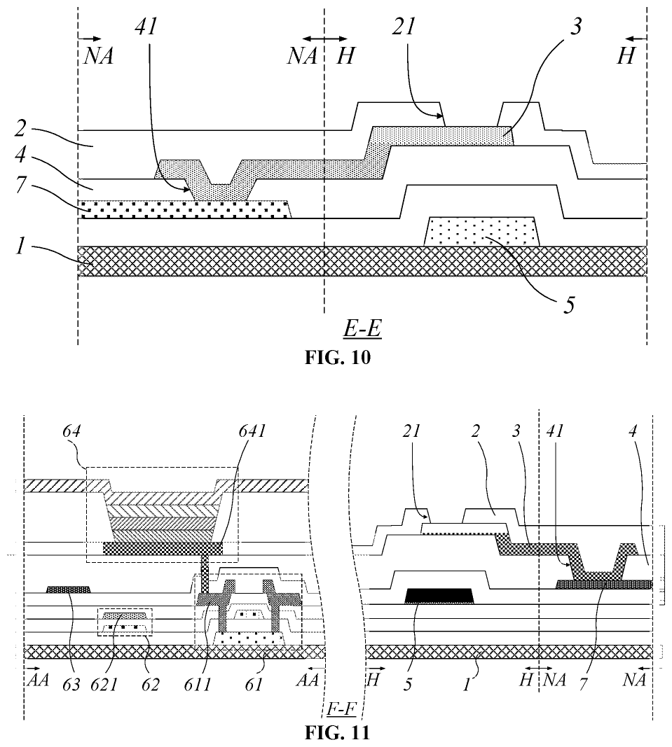

FIG. 10 is a cross-sectional view taken along line E-E of the display panel in FIG. 1 according to embodiments of the present disclosure.

Please refer to FIG. 10, the display panel of embodiments of the present disclosure further includes: a second metal layer 7 located between the second insulating layer 4 and the base substrate 1; The second insulating layer 4 is provided with a second via hole 41 located in the non-display area NA. The second via hole 41 exposes the second metal layer 7; At the second via hole 41, the first metal layer 3 and the second metal layer 7 are electrically connected.

The second metal layer 7 is exposed at the second via hole 41, so that the first metal layer 3 can be electrically connected with the second metal layer 7 at the second via hole 41. The second connecting signal wire can be located at the second metal layer 7. Meanwhile, the first connecting signal wire is electrically connected with the third metal layer 3, and the second connecting signal wire in the second metal layer 7 is also electrically connected with the third metal layer 3, so as to realize the indirect electrical connection between the first connecting signal wire and the second connecting signal wire. Since the first connecting signal wire and the second connecting signal wire are electrically connected in an indirect manner, the space between the first metal layer 3 and the base substrate 1 along the thickness direction can be more fully utilized, thereby reducing the area occupied by the non-display area NA and increasing the proportion of display area AA.

Furthermore, please refer to FIG. 10, the second via hole 41 is located outside the wire routing area H.

When the second via hole 41 is not easy to be arranged in the wire routing area H, the second via hole 41 can be arranged outside the wire routing area H. Considering that the first metal layer 3 is electrically connected to the second metal layer 7 at the second via hole 41, a signal wire located in the first metal layer 3 can be arranged, and the signal wire extends from the first via hole 21 to the second via hole 41, simplifying the complexity of the first metal layer 3.

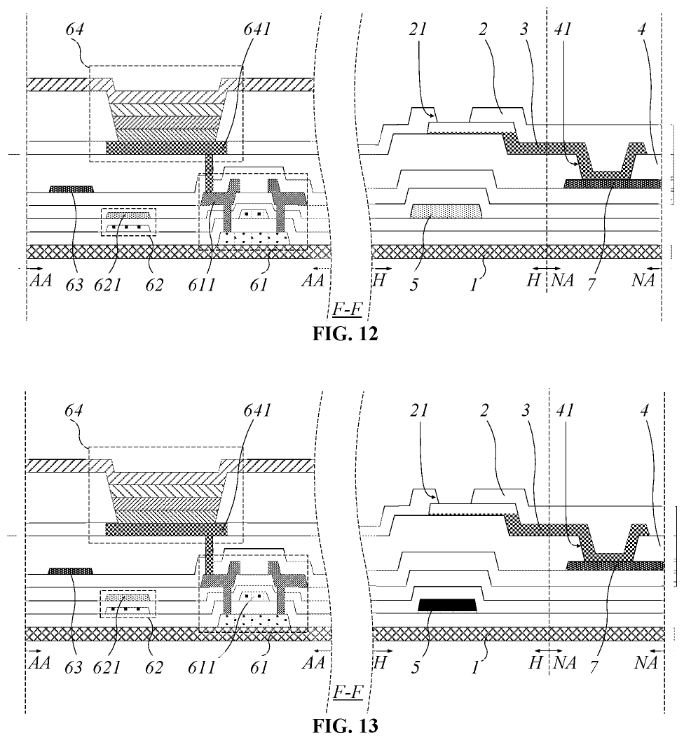

FIG. 11 is a cross-sectional view taken along line F-F of the display panel in FIG. 1 according to embodiments of the present disclosure. FIG. 12 is another cross-sectional view taken along line F-F of the display panel in FIG. 1 according to embodiments of the present disclosure. FIG. 13 is another cross-sectional view taken along line F-F of the display panel in FIG. 1 according to embodiments of the present disclosure.

Further, please refer to FIG. 11 to FIG. 13, the display area AA includes a plurality of light-emitting devices 64, a plurality of thin film transistors 61, a plurality of capacitors 62, and a plurality of first signal wires 63; A thin film transistor of the plurality of thin film transistors 61 include a first transistor electrode 611, and a capacitor of the plurality of capacitors 62 includes a first capacitor electrode 621, a light-emitting device of the plurality of light-emitting devices 64 includes a first device electrode 641; The first device electrode 641, the first transistor electrode 611, the first capacitor electrode 621, and a first signal wire of the plurality of first signal wires 63 are arranged in different layers; The first device electrode 641 is located in the first metal layer 3; The first metal spacer 5 and at least one of the first signal wire 63, the first transistor electrode 611, and the first capacitor electrode 621 are arranged in the same layer; The first signal wire 63 is located on the second metal layer 7.

The thin film transistor 61, the capacitor 62, and the first signal wire 63 located in the display area AA can be used to form a pixel circuit of the display panel to control the light-emitting device 64 located in the display area AA to emit light. Exemplarily, the light-emitting device 64 may be an organic light emitting diode (OLED), and the first device electrode 641 may be an anode of the light emitting device 64. The first transistor electrode 611 of the thin film transistor 61 may be a gate electrode or a drain electrode. The first capacitor electrode 621 of the capacitor 62 may be any electrode of the capacitor 62. The first signal wire 63 may be a positive power line. The first device electrode 641, the first transistor electrode 611, the first capacitor electrode 621, and the first signal wire 63 are arranged in different layers. Generally, along the thickness direction of the display panel, the first transistor electrode 611, the first capacitor electrode 621, and the first signal wire 63 are located between the first device electrode 641 and the base substrate 1. Therefore, the first device electrode 641 is arranged in the first metal layer 3, and the first metal spacer 5 and at least one of the first signal wire 63, the first transistor electrode 611, and the first capacitor electrode 621 are arranged in the same layer. The part of the first metal layer 3 exposed in the first via hole 21 and the first device electrode 641 can be fabricated simultaneously, which facilitates the fabrication of the part of the first metal layer 3 exposed in the first via hole 21, and does not significantly increase the thickness of the display panel in some embodiments of the present disclosure. The first metal spacer 5 and the first device electrode 641 can also be produced simultaneously, and/or, the first metal spacer 5 and the first transistor electrode 611 can be produced simultaneously, and/or, the first metal spacer 5 and the first capacitor electrode 621 can be produced synchronously, facilitating the fabrication of the first metal pad 5. At the same time, the distance from the first via hole 21 of the first insulating layer 2 to the base substrate 1 is greater than the distance from the first insulating layer 2 to the base substrate 1 in the display area AA. There should be at least one first metal spacer 5, and each first metal spacer 5 is respectively arranged in the same layer as each one of the first signal wire 63, the first transistor electrode 611, and the first capacitor electrode 621.

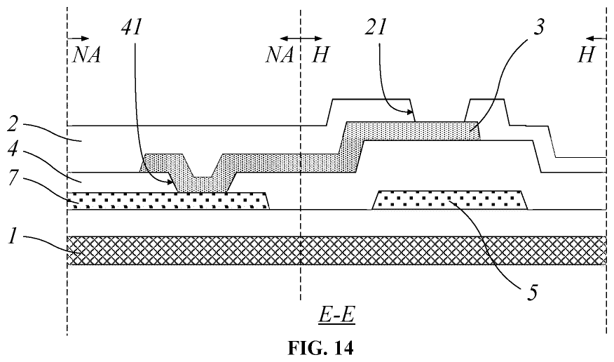

FIG. 14 is another cross-sectional view taken along line E-E of the display panel in FIG. 1 according to embodiments of the present disclosure.

Further, please refer to FIG. 14, the first metal spacer 5 is located in the second metal layer 7.

When the first metal spacer 5 and one of the first signal wire 63, the first transistor electrode 611, and the first capacitor electrode 621 are arranged in the same layer, the first metal spacer 5 is located in the second metal layer 7. During the process of making the second metal layer 7, the second metal layer 7 located at the second via hole 41 and the first metal spacer 5 as well as one of the first signal wire 63, the first transistor electrode 611, and the first capacitor electrode 621 can be fabricated simultaneously. Therefore, the manufacturing process of embodiments of the present disclosure can be simplified, and at the same time, the space of the second metal layer 7 in different areas can be more fully utilized.

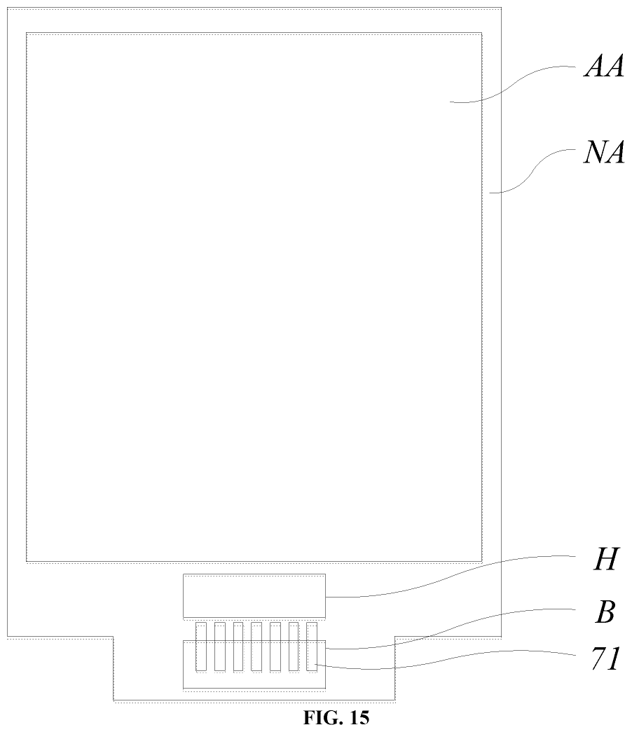

FIG. 15 is a schematic diagram of the routing of the second binding wire in the display panel according to embodiments of the present disclosure.

Further, please refer to FIG. 15, the non-display area NA also includes a bending area B, and the wire routing area H is located between the bending area B and the display area AA; The second via hole 41 is located between the wire routing area H and the bending area B; The second metal layer 7 includes a second binding wire 71, at least part of the second binding wire 71 is located in the bending area B; The second via hole 41 exposes at least part of the second binding wire 71.

At least a part of the second binding wire 71 of the second metal layer 7 is located in the bending area B and used as the second connecting signal wire. When the first connecting signal wire is routed, the first connecting signal wire can be electrically connected to the first metal layer 3 at the first via hole 21, and the first metal layer 3 can be electrically connected to the second binding wire 71 at the second via hole 41 to achieve the purpose of wire routing. In some embodiments of the present disclosure, after the display panel is bound and connected, the second binding wire 71 is bent together with the bending area B.

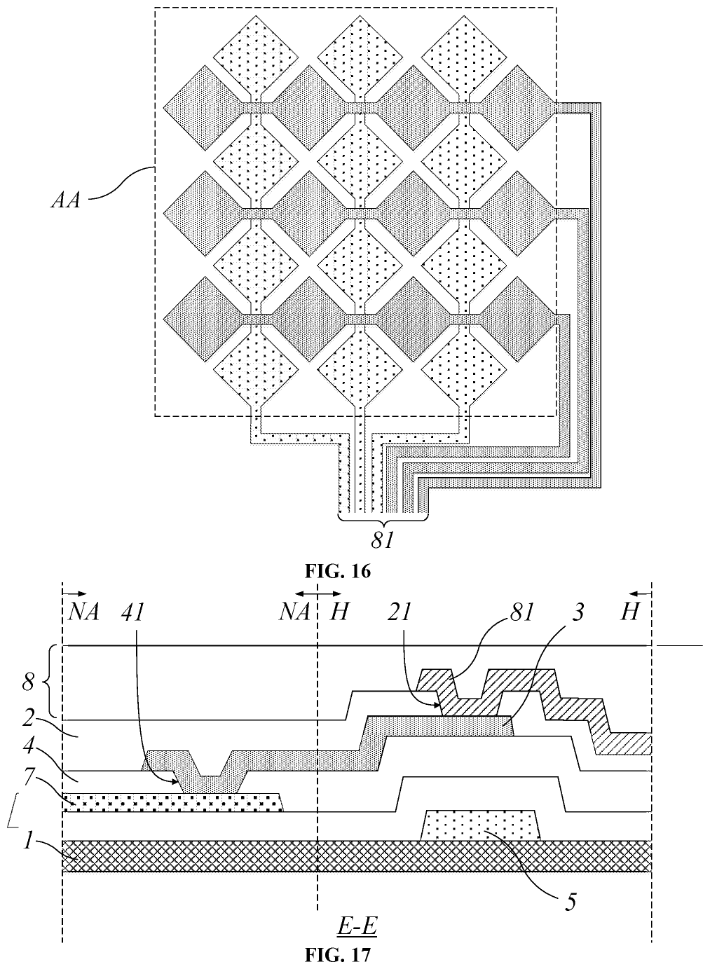

FIG. 16 is a top view of the touch layer of the display panel according to embodiments of the present disclosure. FIG. 17 is another cross-sectional view taken along line E-E of the display panel in FIG. 1 according to embodiments of the present disclosure.

Further, please refer to FIG. 16 and FIG. 17. The display panel in some embodiments of the present disclosure further includes: a touch layer 8 which includes a touch signal wire 81. At the first via hole 21, the touch signal wire 81 is electrically connected to the first metal layer 3.

In some embodiments of the present disclosure, in the display panel, the touch function is realized by setting the touch layer 8. For the convenience of explanation, some embodiments of the present disclosure take the form of mutual capacitance adopted by the touch layer 8 as an example for illustration, and the touch layer 8 may also adopt the form of self-capacitance. The touch signal wire 81 of the touch layer 8 is used for transmitting the touch signals. When a touch operation is performed, the capacitance between the touch electrodes at the touch position corresponding to the touch layer 8 changes, so the electrical signal generated by the touch signal wire 81 that is electrically connected to the touch electrodes will change, forming a touch signal. The touch signal wire 81 leads the touch signal out to the non-display area; In some embodiments of the present disclosure, after the display panel is bound with a circuit board with a chip, the chip can identify the touch position according to the touch signal. The touch signal wire 81 is used as the first connecting signal wire to be electrically connected to the first metal layer 3 at the first via hole 21, that is, to be electrically connected to the corresponding first binding wire 31 located on the first metal layer 3 to realize the routing of the touch signal wire 81, where the first binding wire 31 is used as the second connecting signal wire. The touch signal can be transmitted to the bending area B through the corresponding first binding wire 31 in the first metal layer 3, and then transmitted to the chip through the binding connection between the display panel and the circuit board with the chip.

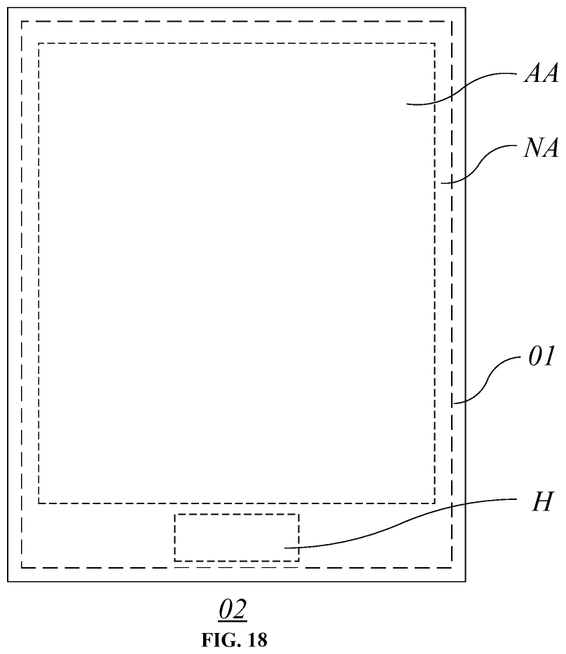

FIG. 18 is a schematic structural diagram of a display device according to embodiments of the present disclosure.

Referring to FIG. 18, embodiments of the present disclosure also provide a display device 02, including the display panel 01 of embodiments of the present disclosure. The display device provided in embodiments of the present disclosure may be any products or components with a display function, such as a mobile phone, a tablet, a television, a monitor, a laptop, a digital photo frame, a navigation device, and so on.

In summary, in the display panel and the display device provided by embodiments of the present disclosure, the first via hole located in the first insulating layer is arranged in the wire routing area and exposes the first metal layer which is provided for electrically connecting of the signal wires requiring wire routing. The second insulating layer is located on the side of the first metal layer close to the base substrate. The distance from the side surface of the second insulating layer away from the base substrate to the side surface of the base substrate close to the second insulating layer, is D1 in the wire routing area and D2 in the display area, where D1 is greater than D2. Therefore, when fabricating the packaging layer, the portion of the first metal layer located in the first via hole is closer to the mask plate of the packaging layer than the portion of the first metal layer located in the display area. Therefore, it is difficult for the packaging layer material to enter the first via hole, allowing the first metal layer to be more fully exposed in the first via hole and improving the electrical connection quality between the signal wire and the first metal layer.

The above description is only a specific implementation of the present disclosure, but the scope of protection of the present disclosure is not limited thereto. Any persons of ordinary skill in the art familiar with the technical field of the present disclosure can easily conceive various equivalent modifications or substitutions within the scope of the technology disclosed in the present disclosure, and such modifications or substitutions should be covered within the scope of protection of the present disclosure. Therefore, the scope of protection of the present disclosure should be determined by the scope of protection of the claims.

What is claimed is:

1. A display panel, comprising:
a display area and a non-display area;
a wire routing area, located in the non-display area;
a base substrate, a first insulating layer and a first metal layer, wherein
the first metal layer is located between the first insulating layer and the base substrate; and
the first insulating layer comprises a first via hole exposing at least part of the first metal layer;
a second insulating layer, located between the first metal layer and the base substrate, wherein the second insulating layer is in contact with the first metal layer;
in the wire routing area, along a thickness direction of the display panel, a distance from a side surface of the second insulating layer away from the base substrate to a side surface of the base substrate close to the second insulating layer being D1; and
in the display area, along the thickness direction of the display panel, a distance from the side surface of the second insulating layer away from the base substrate to the side surface of the base substrate close to the second insulating layer being D2, wherein
$$D 1 > D 2 > 0 .$$

2. The display panel according to claim 1, further comprising:
a first metal spacer located in the wire routing area, wherein
the first metal spacer is arranged between the second insulating layer and the base substrate.

3. The display panel according to claim 2, wherein:
the display area comprises a plurality of thin film transistors, a plurality of capacitors, and a plurality of first signal wires;
a thin film transistor of the plurality of thin film transistors comprises a first transistor electrode;
a capacitor of the plurality of capacitors comprises a first capacitor electrode;
the first transistor electrode, the first capacitor electrode, and a first signal wire of the plurality of first signal wires are arranged in different layers;
the first signal wire is located in the first metal layer; and
the first metal spacer and at least one of the first transistor electrode and the first capacitor electrode are arranged in a same layer.

4. The display panel according to claim 1, wherein:
the non-display area further comprises a bending area, the wire routing area being located between the bending area and the display area;
the first metal layer comprises a first binding wire, at least part of the first binding wire being located in the bending area; and
the first via hole exposes at least part of the first binding wire.

5. The display panel according to claim 2, further comprising:
a second metal layer located between the second insulating layer and the base substrate, wherein
the second insulating layer includes a second via hole located in the non-display area; and
the second via hole exposes the second metal layer, wherein the first metal layer and the second metal layer is electrically connected at the second via hole.

6. The display panel according to claim 5, wherein the second via hole is located outside the wire routing area.

7. The display panel according to claim 5, wherein:
the display area comprises a plurality of light-emitting devices, a plurality of thin film transistors, a plurality of capacitors, and a plurality of first signal wires;
a thin film transistor of the plurality of thin film transistors comprises a first transistor electrode;
a capacitor of the plurality of capacitors comprises a first capacitor electrode;
a light-emitting device of the plurality of light-emitting devices comprises a first device electrode;
the first device electrode, the first transistor electrode, the first capacitor electrode, and a first signal wire of the plurality of first signal wires are arranged in different layers;
the first device electrode is located in the first metal layer;
the first metal spacer and at least one of the first signal wire, the first transistor electrode, and the first capacitor electrode are arranged on a same layer; and
the first signal wire is located in the second metal layer.

8. The display panel according to claim 5, wherein the first metal spacer is located in the second metal layer.

9. The display panel according to claim 5, wherein:
the non-display area further comprises a bending area, the wire routing area being located between the bending area and the display area;
the second via hole is located between the wire routing area and the bending area;
the second metal layer comprises a second binding wire, at least part of the second binding wire being located in the bending area; and
the second via hole exposes at least part of the second binding wire.

10. The display panel according to claim 2, wherein:
along the thickness direction of the display panel, the first metal spacer at least partially overlaps with the first via hole.

11. The display panel according to claim 2, wherein:
along the thickness direction of the display panel, at least a part of the first metal spacer does not overlap with the first via hole.

12. The display panel according to claim 11, wherein:
in the wire routing area, along the thickness direction of the display panel, a distance from the side surface of the second insulating layer, covering the first metal spacer and away from the base substrate, to the side surface of the base substrate, close to the second insulating layer, being D11; and
in the wire routing area, along the thickness direction of the display panel, a distance from the side surface of a part of second insulating layer not covering the first metal spacer and away from the base substrate to the side surface of the base substrate close to the second insulating layer being D12, wherein D11>D12>0.

13. The display panel according to claim 1, further comprising:
a touch layer, comprising a touch signal wire,
wherein in the first via hole, the touch signal wire is electrically connected to the first metal layer.

14. The display panel according to claim 13, wherein at least part of the touch signal wire is located in the non-display area.

15. A display device, comprising:
a display panel, comprising:
a display area and a non-display area;
a wire routing area, located in the non-display area;
a base substrate, a first insulating layer and a first metal layer, wherein
the first metal layer is located between the first insulating layer and the base substrate; and
the first insulating layer comprises a first via hole exposing at least part of the first metal layer;
a second insulating layer, located between the first metal layer and the base substrate, wherein the second insulating layer is in contact with the first metal layer;
in the wire routing area, along a thickness direction of the display panel, a distance from a side surface of the second insulating layer away from the base substrate to a side surface of the base substrate close to the second insulating layer being D1; and
in the display area, along the thickness direction of the display panel, a distance from the side surface of the second insulating layer away from the base substrate to the side surface of the base substrate close to the second insulating layer being D2, wherein
$$D 1 > D 2 > 0 .$$

16. The display device according to claim 15, further comprising:
a first metal spacer located in the wire routing area, wherein
the first metal spacer is arranged between the second insulating layer and the base substrate.

17. The display device according to claim 15, wherein:
the non-display area further comprises a bending area, the wire routing area being located between the bending area and the display area;
the first metal layer comprises a first binding wire, at least part of the first binding wire being located in the bending area; and
the first via hole exposes at least part of the first binding wire.

18. The display device according to claim 16, further comprising:
a second metal layer located between the second insulating layer and the base substrate, wherein
the second insulating layer includes a second via hole located in the non-display area; and
the second via hole exposes the second metal layer, wherein the first metal layer and the second metal layer is electrically connected at the second via hole.

19. The display device according to claim 16, wherein:
along the thickness direction of the display panel, at least a part of the first metal spacer does not overlap with the first via hole.

20. The display device according to claim 15, further comprising:
a touch layer, comprising a touch signal wire,
wherein in the first via hole, the touch signal wire is electrically connected to the first metal layer.
